(19) United States
(12) Patent Application Publication
(10) Pub. No.: US 2021/0066075 A1
(43) Pub. Date: Mar. 4, 2021

(54) STRUCTURES INCLUDING DIELECTRIC LAYERS AND METHODS OF FORMING SAME

(71) Applicant: ASM IP Holding B.V., Almere (NL)

(72) Inventors: Yan Zhang, Tokyo (JP); Toshihisa Nozawa, Kawasaki-shi (JP)

(21) Appl. No.: 17/003,919

(22) Filed: Aug. 26, 2020

Related U.S. Application Data
(60) Provisional application No. 62/893,645, filed on Aug. 29, 2019.

(51) Int. Cl. H01L 21/02; C23C 16/455

(52) U.S. Cl. CPC H01L 21/02274; H01L 21/0228; C23C 16/45553; H01L 21/02216; C23C 16/45536; H01L 21/02211

(57) ABSTRACT

Methods of forming structures having dielectric films with improved properties, such as, for example, improved elastic modulus and/or dielectric constant are disclosed. Exemplary films can be formed using a cyclic deposition process. Exemplary methods use activated species to cleave (e.g., symmetric-structured) precursor molecules to form the high quality dielectric layers.

### CROSS-REFERENCE TO RELATED APPLICATIONS

This application claims the benefit of U.S. Provisional Application No. 62/893,645, filed on Aug. 29, 2019, in the United States Patent and Trademark Office, the disclosure of which is incorporated herein in its entirety by reference.

### FIELD OF INVENTION

The present disclosure generally relates to methods and systems for forming structures suitable for the manufacture of electronic devices. Examples of the disclosure relate to methods and systems for forming a structure including a low-k dielectric film using a plasma-enhanced cyclic deposition process.

### BACKGROUND OF THE DISCLOSURE

During the manufacture of electronic devices, deposition of amorphous films with a low dielectric constant (low-K) is desirable for several applications, including insulation and mitigation of crosstalk within integrated circuits. Low-K films can be deposited using a variety of techniques, including, for example, plasma-enhanced chemical vapor deposition (PECVD). Typically, with PECVD, precursor molecules are excessively dissociated in gas phase, which results in deposition of a relatively porous amorphous film. Dielectric material deposition using PECVD may have a relatively low K value; however, the film may also have an undesirably low elastic modulus.

PECVD methods using a neutral beam have resulted in improved elastic modulus and production of symmetric-structured films. However, the neutral beam methods are higher in cost and may be difficult to implement.

Accordingly, improved systems and methods for forming high-quality material, such as high-quality dielectric material (e.g., silicon oxide) on a substrate, and structures formed using such methods and/or systems are desired. Any discussion of problems and solutions described in this section has been included solely for the purpose of providing a context for the present disclosure and should not be taken as an admission that any or all of the discussion was known at the time of the present disclosure.

### SUMMARY OF THE DISCLOSURE

Various embodiments of the present disclosure relate to methods of forming structures that include high-quality insulating or dielectric films. While the ways in which various embodiments of the present disclosure address drawbacks of prior methods and systems are discussed in more detail below, in general, various embodiments of the disclosure provide improved methods and systems that include the use of activated species for forming films having desired properties.

In accordance with an embodiment of the disclosure, a method of depositing a material on a surface of a substrate, including the steps of: (a) providing the substrate within a reaction chamber; (b) providing a precursor within the reaction chamber, wherein the precursor is adsorbed on the surface of the substrate to form an adsorbed species; (c) purging the reaction chamber after providing the precursor; and (d) exposing the adsorbed species to an activated species to cleave the adsorbed species and thereby form a cleaved adsorbed species on the surface of the substrate is provided. The precursor can be a symmetric-structured precursor. The symmetric-structured precursor can be symmetrical across a horizontal axis. The symmetric-structured precursor can comprise oxygen. In accordance with some examples of the disclosure, the symmetric-structured precursor comprises a linear backbone and a plurality of organic (e.g. methyl, ethyl, propyl) groups attached to the backbone. The precursor can comprise a Si—O bond. The precursor can comprise a silicon and an organic group. In accordance with various aspects of these embodiments, the precursor can comprise a linear backbone comprising silicon-oxygen and silicon-carbon-silicon bonds along the backbone and on the side chains.

By way of particular examples, the symmetric-structured precursor can comprise one or more of dimethyldimethoxysilane (DMDMOS), tetramethyl-1,3-dimethoxydisiloxane (DMOTMDS), tetraethyl-1,3-dimethoxydisiloxane, tetrapropyl-1,3-dimethoxydisiloxane, tetrabutyl-1,3-dimethoxydisiloxane, tetramethyl-1,3-diethoxydisiloxane, tetramethyl-1,3-dipropoxydisiloxane, tetraethyl-1,3-diethoxydisiloxane, tetraethyl-1,3-dipropoxydisiloxane, tetrapropyl-1,3-diethoxydisiloxane, tetrapropyl-1,3-dipropoxydisiloxane, tetrabutyl-1,3-diethoxydisiloxane, or tetrabutyl-1,3-dipropoxydisiloxane. The activated species can be formed within the reaction chamber.

The activated species can be formed using a remote plasma. A gas for forming the activated species may comprise argon, helium, or both argon and helium. A gas for forming the activated species may additionally or alternatively comprise hydrogen gas. During step (d), the plasma may be pulsed or supplied continuously. The method can comprise a PEALD process. The method can further comprise a step of purging the reaction chamber after step (d). A reactant gas may be continuously fed to the reaction chamber during steps (a) through (d). During step (d), one or more organic groups may be cleaved from the adsorbed species, e.g. from the ends of the precursor molecules. A pressure within the reaction chamber may be between about 500 Pa and about 1000 Pa or about 1000 Pa and about 5000 Pa. A temperature within the reaction chamber may be between about 70° C. and about 50° C. or about 50° C. and about 30° C. A low-K dielectric film may be formed on a substrate by repeating steps (a) through (d) until a desired thickness of the film is achieved.

A structure may be formed according to a method as disclosed herein.

A reactor system can be configured to perform a method as disclosed herein.

These and other embodiments will become readily apparent to those skilled in the art from the following detailed description of certain embodiments having reference to the attached figures; the disclosure not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a PEALD process sequence according to an embodiment of the disclosure.

FIG. 2 illustrates a reaction occurring during one cycle of a PEALD process according to an embodiment of the disclosure.

FIG. 3 (A)-(D) are graphs illustrating the relationship between low-K film growth per cycle (GPC) (nm/cycle) and (A) feed time (seconds), (B) RF on time (seconds), and (C) purge time (seconds) according to an embodiment of the present disclosure. (D) illustrates the relationship between thickness (nm) of the film and a number of cycles according to an embodiment of the present disclosure.

FIG. 4A and FIG. 4B illustrate Fourier Transform Infrared (FTIR) spectrums of Si—CH₃ films formed under different process conditions according to embodiments of the disclosure. The exploded view inset of FIG. 4A is provided in FIG. 4B.

FIG. 5 illustrates FTIR spectrums of Si—CH₃ films using a pulsed plasma step and a continuous plasma step according to embodiments of the disclosure.

FIG. 6 illustrates a schematic representation of a PEALD (plasma-enhanced atomic layer deposition) apparatus for depositing a dielectric film usable according to embodiments of the present disclosure.

FIG. 7 illustrates a schematic of a structure formed according to embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses and obvious modifications and equivalents thereof. Thus, it is intended that the scope of the disclosure should not be limited by the particular embodiments described below.

The present disclosure generally relates to methods of forming structures, such as structures suitable for forming electronic devices, to reactor systems for performing the methods, and to structures formed using the methods. By way of examples, the systems and methods described herein can be used to form (e.g., amorphous) high-quality insulating or dielectric layers. In some embodiments, the layers are formed using a cyclic process using one or more of an inert process gas (e.g., argon and helium) and a reducing process gas (e.g., hydrogen). For example, process gas used in the cyclic process can contain one or more of argon, helium, and hydrogen. In some embodiments, the layers are formed using a symmetric-structured precursor.

In this disclosure, “gas” may include material that is a gas at room temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas. In some embodiments, the term “precursor” can refer to a compound that participates in the chemical reaction that produces another compound, and particularly to a compound that constitutes a film matrix or a main skeleton of a film; the term “reactant” can be used interchangeably with the term precursor (e.g., Ar, He, and/or H₂). The term “inert gas” can refer to a gas that does not take part in a chemical reaction and/or a gas that excites a precursor when RF power is applied, but unlike a reactant, it may not become a part of a film matrix to an appreciable extent. Exemplary inert gases include He, Ar, N₂, and any combination thereof. Hydrogen can also be used as an inert gas and/or as a reducing agent.

As used herein, the term “substrate” may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as a Group II-VI or Group III-V semiconductor, and can include one or more layers overlying or underlying the bulk material. Further, the substrate can include various features, such as recesses, lines, and the like formed within or on at least a portion of a layer of the substrate. Features can have relatively high aspect ratios, ranging from, for example, about 1 to about 50 or about 3 to about 20.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, the term “cyclic deposition” can refer to the sequential introduction of precursors (reactants) into a reaction chamber to deposit a film over a substrate and includes deposition techniques, such as atomic layer deposition and cyclical chemical vapor deposition.

As used herein, the term “cyclical chemical vapor deposition” can refer to any process wherein a substrate is sequentially exposed to two or more volatile precursors, which react and/or decompose on a substrate to produce a desired deposition.

As used herein, the term “atomic layer deposition” (ALD) can refer to a vapor deposition process in which deposition cycles, typically a plurality of consecutive deposition cycles, are conducted in a reaction chamber. Typically, during each cycle, the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, a reactant (e.g., another precursor, reaction gas, reducing gas, and/or inert gas) may subsequently be introduced into the reaction chamber for use in converting the chemisorbed precursor to the desired material on the deposition surface. Typically, this reactant is capable of further reaction with the precursor (e.g., cleaving a portion of the adsorbed precursor). Further, purging steps may also be utilized during each cycle to remove excess precursor from the reaction chamber and/or remove excess reactant and/or reaction byproducts from the reaction chamber after conversion of the chemisorbed precursor. Further, the term “atomic layer deposition,” as used herein, is also meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas. PEALD refers to an ALD process, in which a plasma is applied during one or more of the ALD steps.

As used herein, a “structure” can include a substrate as described herein. Structures can include one or more layers, overlying the substrate, which are formed as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In this disclosure, “continuously” can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments.

In this disclosure, symmetric-structured precursor can refer to a precursor that has symmetry across a horizontal plane of symmetry. For example, DMDMOS is symmetrical above and below across the horizontal axis, where each chemical (e.g., organic) group above and below the horizontal axis is the same, namely, a methyl group.

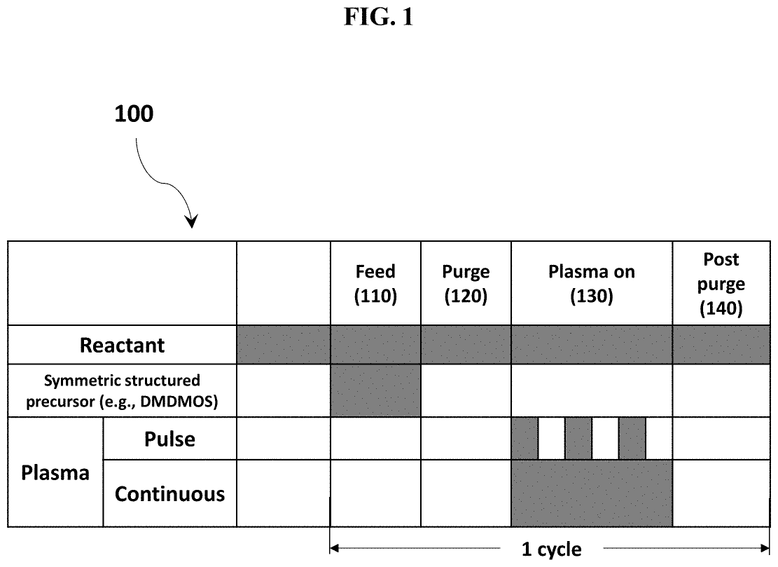

Turning now to the figures, FIG. 1 illustrates a schematic representation of a deposition process 100 in accordance with at least one embodiment of the disclosure. In the illustrated process, a reactant gas (e.g., He, Ar and/or H₂) is provided throughout a deposition cycle and optionally before the deposition cycle, as illustrated. Each deposition cycle beings with a feed step 110, wherein a precursor gas is provided to the reaction space, and then shut off. Then, in a purge step 120, the precursor gas is purged from the reaction space. Then, in a plasma on step 130, plasma (e.g., RF) power is provided and shut off. The plasma may be provided in two or more pulses, or it may be provided continuously during step 130. Then, in a post purge step 140, any excess precursor and/or byproduct can be purged from the reaction space. The deposition cycle may be repeated until a desired thickness of the deposited material is reached. The process can be used to form an insulating or low-κ dielectric material layer. For example, one or more of an oxide, a nitride, and a carbide layer may be formed using process 100. For example, the layer can be or include one or more of SiO₂, SiN, SiOC, SiCN, SiC, SiON, SiOCN, SiBN, SiBO, GeOₓ, GeN, AlO_{X}, TiO₂, and TaO₂.

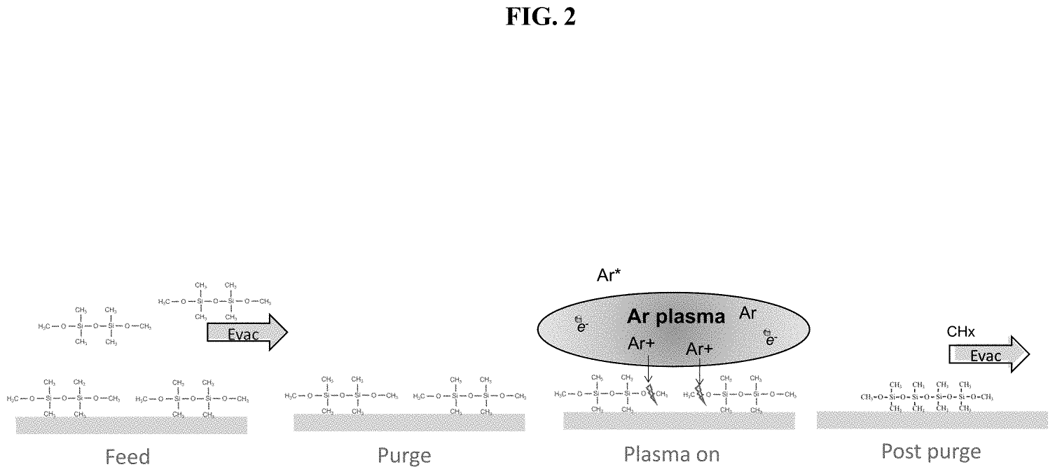

FIG. 2 illustrates a reaction during the deposition cycle according to an exemplary embodiment of the disclosure. In the illustrated example, a precursor, e.g., a symmetric-structured precursor, such as dimethyldimethoxysilane (DMDMOS) precursor is fed into the reaction chamber. In other embodiments, a different symmetric-structured precursor is used. In some embodiments, an oxygen containing symmetric-structured precursor is used. In some embodiments, the symmetric-structured precursor comprises bonds along the horizontal plane of symmetry that are easier to break than the bonds across the horizontal plane of symmetry. In some embodiments, the precursor is also symmetric across a vertical plane of symmetry. Examples of other symmetric-structured precursors that may be used include tetramethyl-1,3-dimethoxydisiloxane (DMOTMDS), tetraethyl-1,3-dimethoxydisiloxane, tetrapropyl-1,3-dimethoxydisiloxane, tetrabutyl-1,3-dimethoxydisiloxane, tetramethyl-1,3-diethoxydisiloxane, tetra methyl-1,3-dipropoxydisiloxane, tetraethyl-1,3-diethoxydisiloxane, tetraethyl-1,3-dipropoxydisiloxane, tetra propyl-1,3-diethoxydisiloxane, tetra propyl-1,3-dipropoxydisiloxane, tetrabutyl-1,3-diethoxydisiloxane, tetrabutyl-1,3-dipropoxydisiloxane, and the like. In other embodiments, a non-symmetric-structured precursor is used.

In this example, after DMDMOS precursor is fed into the reaction chamber, a purge step evacuates any excess precursor that has not adhered to or adsorbed onto the substrate. Following the purge, when the plasma is turned on, Ar ions cleave methyl end groups off the DMDMOS species. Then, the post purge step evacuates the methyl group byproducts from the reaction chamber. As illustrated, the free oxygen groups at the ends of the DMDMOS can join to create a film.

In some embodiments, the plasma step is provided in a pulse. Pulsed plasma may enhance purging of any residual precursor and/or any byproducts from the reaction chamber, and prevents them from being incorporated into the film. In some embodiments, in which a pulsed plasma is used, each pulse of RF power may be provided for less than 0.1 seconds, less than 0.05 seconds, or less than 0.04 seconds. In some embodiments, the duration of RF power is 0.04, 0.05, 0.1, 0.2, 0.3, 0.4, 0.5, 0.6, 0.7, 0.8, 0.9, 1.0, 2.0, 3.0, 4.0, or 5.0 seconds, and ranges between any two of the foregoing numbers. The duration of the off time in a pulse cycle can depend on the other process conditions, such as flow rate, pressure, and the like. In accordance with particular examples of the disclosure, a duration of the off time is longer than a duration of the residence time for the precursor within the reaction chamber. In some embodiments, the plasma condition is tuned so as not to break the original symmetric structure in the precursor.

In some embodiments, a remote plasma is used. In some embodiments, a direct plasma is used.

In some embodiments, the temperature within the reaction chamber during one or more of steps 110, 120, 130 and 140 as illustrated in FIG. 2 is between about 50 and 70° C. or between about 30 and 50° C. In some embodiments, the pressure within the reaction chamber during one or more of steps 110, 120, 130, and 140 as illustrated in FIG. 2 is between about 500 and about 1000 Pa or about 1000 and about 5000 Pa.

In some embodiments, during the PEALD process, a power of an RF generator used to form the plasma can be between about 20 W and about 200 W, about 40 W and about 150 W, or about 20 W and about 50 W. In some embodiments, no bias is applied. In other embodiments, a low bias may be applied. For example, the bias between a shower head and a susceptor can be between about 2 W and about 50 W, about 5 W and about 30 W, or about 2 W and about 15 W.

In some embodiments, a PEALD process is used. In other embodiments, other cyclic deposition processes may be used, such as PECVD of a hybrid ALD-CVD process. In the cyclic deposition processes, the cycles may be repeated to form a layer of desired thickness. For example, a layer having a thickness of 2 nm to about 300 nm or about 10 nm to about 150 nm may be formed.

In some embodiments, a flow rate (sccm) of the precursor to the reaction chamber is 15, 80, 160 or ranges of any two of the foregoing numbers with continuous or pulsed plasma.

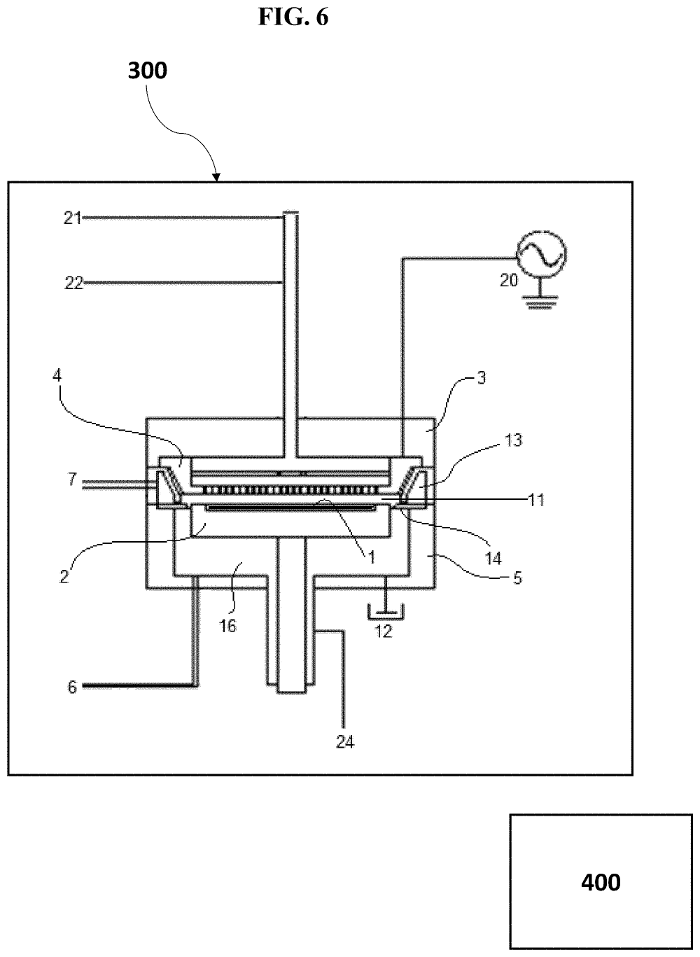

A reactor used in the methods of this disclosure can include any suitable gas-phase reactor. Exemplary reactors include ALD (e.g., PEALD) reactors and CVD (e.g., PECVD) reactors. FIG. 6 is a schematic view of an exemplary PEALD apparatus 300 suitable for use with exemplary embodiments of the disclosure. PEALD apparatus 300 includes a pair of electrically conductive flat-plate electrodes 4, 2 in parallel and facing each other in the interior 11 (reaction zone) of a reaction chamber 3. When RF power (13.56 MHz or 27 MHz) 20 is applied to one side, and the power is electrically grounded on the other side 12, a plasma is excited between the electrodes. A temperature regulator can be provided in a lower stage 2 (the lower electrode), and a temperature of a substrate 1 placed thereon can be maintained at a desired temperature. The upper electrode 4 serves as a shower plate as well, and reactant gas and/or dilution gas, if used, and precursor gas are introduced into the reaction chamber 3 through gas line 21 and gas line 22, respectively, and through shower plate 4. Additionally, in the reaction chamber 3, a circular duct 13 with an exhaust line 7 is provided, through which gas in the interior 11 of the reaction chamber 3 is exhausted. Additionally, a transfer chamber 5 disposed below the reaction chamber 3 is provided with a seal gas line 24 to introduce seal gas into the interior 11 of the reaction chamber 3 via the interior 16 (transfer zone) of the transfer chamber 5 wherein a separation plate 14 for separating the reaction zone and the transfer zone is provided (a gate valve through which a wafer is transferred into or from the transfer chamber 5 is omitted from this figure). The transfer chamber is also provided with an exhaust line 6. In some embodiments, the reactor is used in conjunction with a controller 400 programmed to conduct the PEALD process described herein.

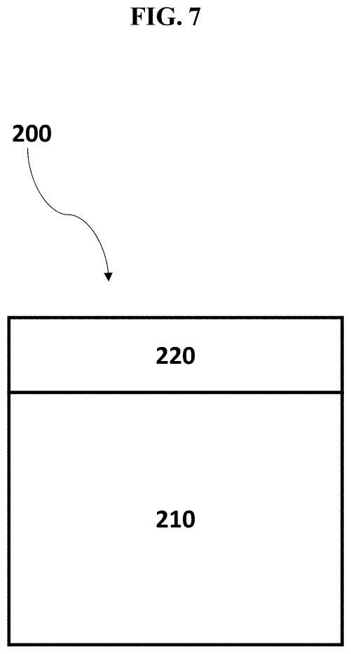

A structure 200 formed by the methods of this disclosure is illustrated in FIG. 7. Structure 200 can include a substrate 210 as described herein. Structures can include one or more layers 220 overlying the substrate, which are formed as described herein.

### EXAMPLES

The examples provided below are meant to be illustrative. Unless otherwise noted, embodiments of the disclosure are not limited to the specific examples provided below.

### Example 1

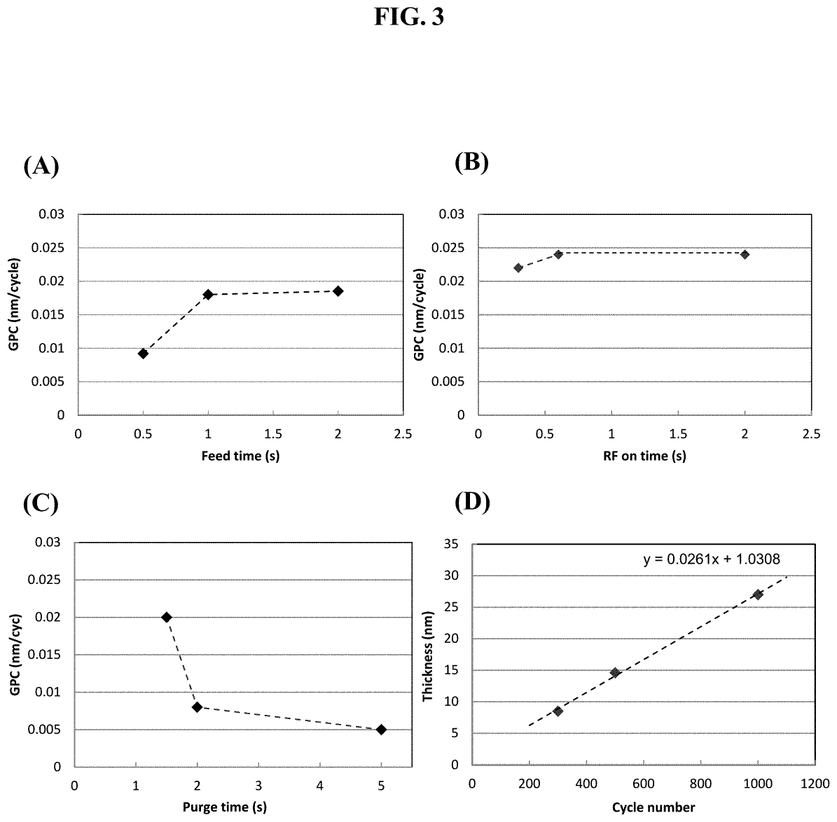

A low-k film was formed by PEALD on a substrate in accordance with the process illustrated in FIGS. 1 and 2. The cycle was performed using a continuous plasma step. FIG. 3 illustrates that the methods of the present disclosure result in ALD-like film growth. FIG. 3A is a graph showing the relationship between growth per cycle (GPC) (nm/cycle) and precursor feed time (seconds), indicating that the growth reached a saturation point after 1 second of feed time. FIG. 3B shows the relationship between GPC and RF on time (seconds), indicating that the growth reached a saturation point after approximately 0.6 seconds of plasma on time. FIG. 3C shows the relationship between GPC and purge time (seconds), indicating that a purge is substantially complete at about 2 seconds. After about 2 seconds, mainly surface reactions are contributing to the GPC. FIG. 3D shows the relationship between thickness of the film (nm) and the number of cycles repeated in the deposition process. FIG. 3D indicates that the thickness of the layer increases proportionally to the number of deposition cycles. The relationship between the two is substantially linear, indicating ALD-like film growth.

### Example 2

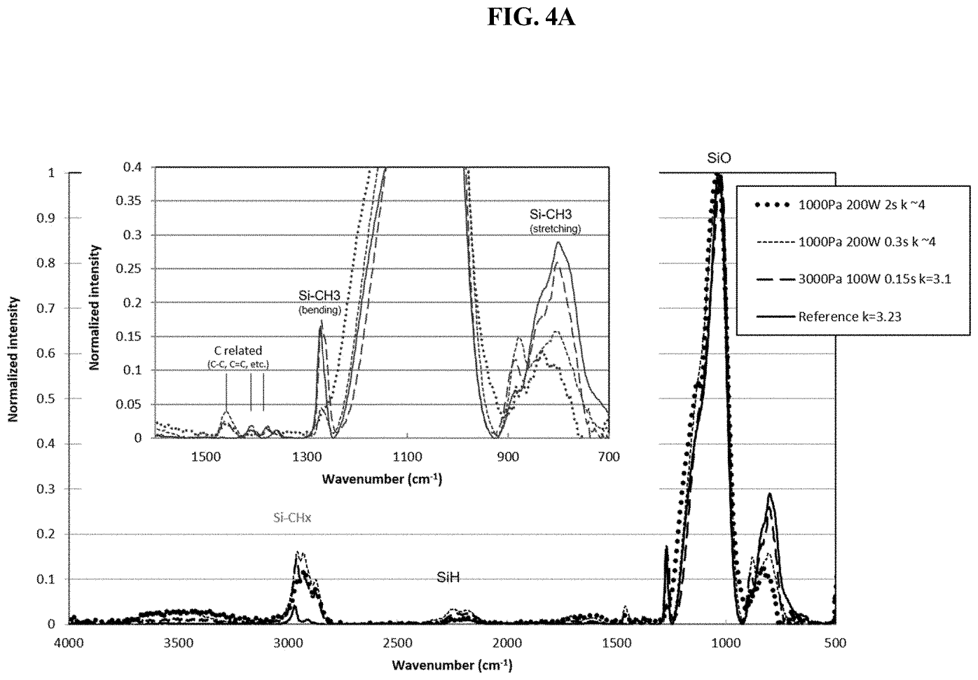

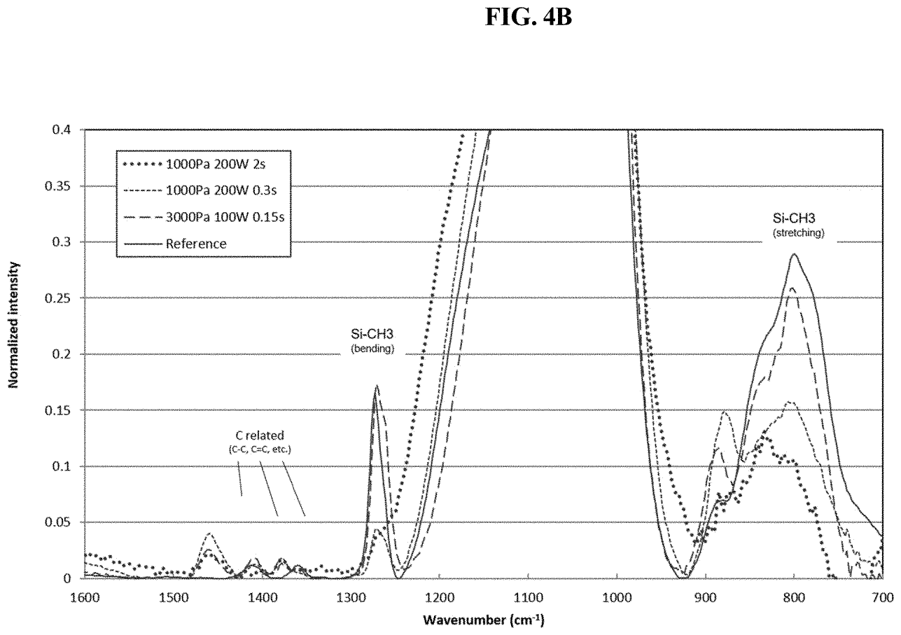

FIGS. 4A and 4B illustrate Fourier Transform Infrared (FTIR) spectrums of Si—CH₃ films formed under different process conditions according to embodiments of the disclosure. Under process conditions of 1000 Pa pressure, 200 W power, and 2 seconds, the k value is about 4. Under 1000 Pa pressure, 200 W power, and 0.3 seconds, the k value is about 4. Under 3000 Pa pressure, 100 W power, and 0.15 seconds, the k value is 3.1. The improved k value under these conditions is a further improvement over the conventional PECVD method (reference), exhibiting a k value of 3.23. The Si—CH₃ peaks increase when plasma ion energies are decreased. This is achieved by increasing the pressure, decreasing the power, and decreasing the plasma on time, keeping the original Si—CH₃ structure in the precursor.

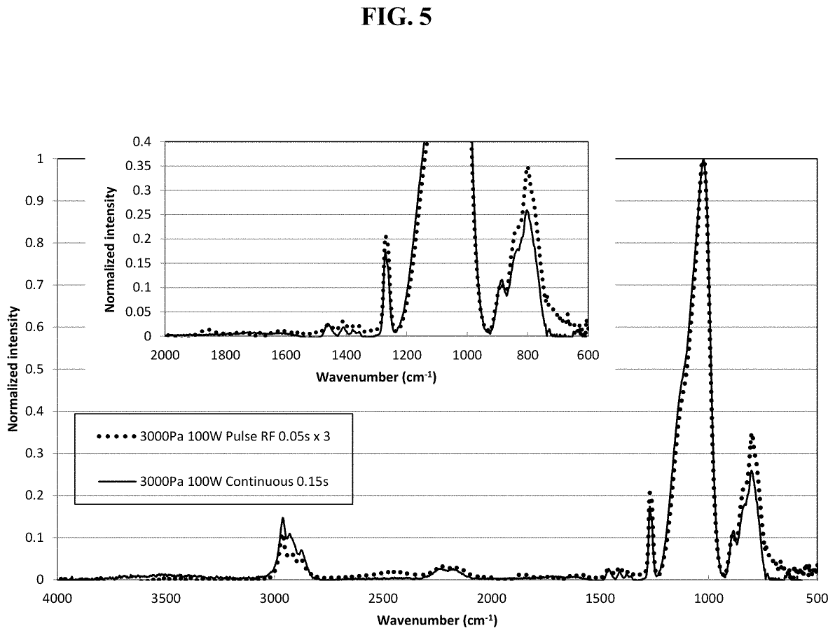

FIG. 5 illustrates FTIR spectrums of Si—CH₃ films formed using pulsed plasma vs continuous plasma under the optimal conditions determined in FIG. 4, specifically 3000 Pa pressure, 100 W power, and 0.15 seconds. Film deposited during pulse discharge has a higher Si—CH₃ peak than that of continuous discharge, which is thought to result from reduction or mitigation of byproduct incorporation in the film.

The example embodiments of the disclosure described above do not limit the scope of the disclosure, since these embodiments are merely examples of the embodiments of the disclosure. Any equivalent embodiments are intended to be within the scope of this disclosure. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

What is claimed is:

1. A method of depositing a material on a surface of a substrate, the method comprising the steps of:
(a) providing the substrate within a reaction chamber;
(b) providing a symmetric-structured precursor within the reaction chamber, wherein the symmetric-structured precursor is adsorbed on the surface of the substrate to form an adsorbed species;
(c) purging the reaction chamber after providing the symmetric-structured precursor; and
(d) exposing the adsorbed species to an activated species to cleave the adsorbed species and thereby form a cleaved adsorbed species on the surface of the substrate.

2. The method of claim 1, wherein the symmetric-structured precursor is symmetrical across a horizontal axis.

3. The method of claim 1, wherein the symmetric-structured precursor comprises oxygen.

4. The method of claim 1, wherein the symmetric-structured comprises one or more of dimethyldimethoxysilane (DMDMOS), tetramethyl-1,3-dimethoxydisiloxane (DMOTMDS), tetraethyl-1,3-dimethoxydisiloxane, tetrapropyl-1,3-dimethoxydisiloxane, tetrabutyl-1,3-dimethoxydisiloxane, tetramethyl-1,3-diethoxydisiloxane, tetramethyl-1,3-dipropoxydisiloxane, tetraethyl-1,3-diethoxydisiloxane, tetraethyl-1,3-dipropoxydisiloxane, tetrapropyl-1,3-diethoxydisiloxane, tetrapropyl-1,3-dipropoxydisiloxane, tetrabutyl-1,3-diethoxydisiloxane, or tetrabutyl-1,3-dipropoxydisiloxane.

5. The method of claim 1, wherein the activated species is formed within the reaction chamber.

6. The method of claim 1, wherein the activated species is formed using a remote plasma.

7. The method of claim 1, wherein a gas for forming the activated species comprises argon, helium, or both argon and helium.

8. The method of claim 1, wherein a gas for forming the activated species comprises a hydrogen gas.

9. The method of claim 1, wherein, during step (d), a plasma is pulsed.

10. The method of claim 1, wherein, during step (d), a plasma is supplied continuously.

11. The method of claim 1, wherein the method comprises a PEALD process.

12. The method of claim 1, further comprising a step of purging the reaction chamber after step (d).

13. The method of claim 1, wherein a reactant gas is continuously fed to the reaction chamber during steps (a) through (d).

14. The method of claim 1, wherein the precursor comprises a Si—O bond.

15. The method of claim 1, wherein the precursor comprises a silicon and an organic group.

16. The method of claim 15, wherein an organic group is cleaved from the adsorbed species in step (d).

17. The method of claim 1, wherein a pressure within the reaction chamber is between about 500 Pa and about 1000 Pa, or about 1000 Pa and about 5000 Pa.

18. The method of claim 1, wherein a temperature within the reaction chamber is between about 70° C. and about 50° C., or about 50° C. and about 30° C.

19. A method of forming a low-κ dielectric film on a substrate by performing the method of claim 1, and repeated steps (a) through (d) until a desired thickness of the film is achieved.

20. A structure formed according to the method of claim 1.

21. A reactor system for performing the steps of claim 1.

22. A method of depositing a material on a surface of a substrate, the method comprising the steps of:
(a) providing the substrate within a reaction chamber;
(b) providing a precursor within the reaction chamber, wherein the precursor is adsorbed on the surface of the substrate to form an adsorbed species;
(c) purging the reaction chamber after providing the precursor; and
(d) exposing the adsorbed species to an activated species to cleave the adsorbed species and thereby forming a layer comprising the material.
